(19) United States
(12) Patent Application Publication
(10) Pub. No.: US 2026/0300585 A1
(43) Pub. Date: Oct. 1, 2026

(54) CLOSED LOOP CONTROL OF FLOWBACK ACTIVITIES

(71) Applicant: Schlumberger Technology Corporation, Sugar Land, TX (US)

(72) Inventors: Graham Taitt, Longford (IE); Andrew Oakes, Houston, TX (US); Cline Johnson, Houston, TX (US)

(21) Appl. No.: 19/097,465

(22) Filed: Apr. 1, 2025

(51) Int. Cl. G06F 30/28; E21B 41/00; E21B 47/003; E21B 47/07

(52) U.S. Cl. CPC G06F 30/28; E21B 41/00; E21B 47/003; E21B 47/07; E21B 2200/20

(57) ABSTRACT

The present disclosure relates to systems and methods for automatically sending data collected at a well during flowback operations to a reservoir modelling platform. The systems and methods send the data to a reservoir modelling platform as the data is received from the well. The systems and methods automate the reporting of the data by displaying on a user interface the data received from the well.

### BACKGROUND OF THE DISCLOSURE

Wellbores are commonly drilled from a surface location or seabed for various exploration and extraction activities. These wellbores are used to access and extract fluid resources like liquid and gaseous hydrocarbons from subterranean formations. The construction of wellbores involves the use of earth-boring equipment such as drill bits for initial drilling and reamers for enlarging the wellbore diameters.

Typically, during flowback at a well, field operators manually record and submit a report containing all processed data for each well. The field operators periodically provide the reports over email to interested parties or provide the written reports to interested parties. The reservoir engineer updates reservoir models based on the report and confirms whether the reservoir and the bottom hole pressure (BHP) are behaving as expected. If a change is required at the well, the change is communicated back to the field operators through email or a phone call.

### SUMMARY

This summary is provided to introduce a selection of concepts that are further described in the detailed description. This summary is not intended to identify key or essential features of the claimed subject matter, nor is it intended to be used as an aid in limiting the scope of the claimed subject matter.

Some implementations relate to a method. The method includes receiving, via a network, data of flowback operations at a well, wherein the data is obtained from a sensor on equipment at the well. The method includes sending the data to a reservoir modelling platform as the data is received from the well using a secure connection established with the reservoir modelling platform. The method includes displaying, on a user interface, the data.

Some implementations relate to a device. The device includes a memory to store data and instructions; and a processor operable to communicate with the memory, wherein the processor is operable to: receive, via a network, data of flowback operations at a well, wherein the data is obtained from a sensor on equipment at the well; sending the data to a reservoir modelling platform as the data is received from the well using a secure connection established with the reservoir modelling platform; and display, on a user interface, the data.

Some implementations relate to a computer-readable storage medium including instructions that, when executed by a processor, cause the processor to: receive, via a network, data of flowback operations at a well, wherein the data is obtained from a sensor on equipment at the well; sending the data to a reservoir modelling platform as the data is received from the well using a secure connection established with the reservoir modelling platform; and display, on a user interface, the data.

Additional features and aspects of implementations of the disclosure will be set forth herein, and in part will be obvious from the description, or may be learned by the practice of such implementations. The features and advantages of such implementations may be realized and obtained by means of the instruments and combinations particularly pointed out in the appended claims. These and other features will become more fully apparent from the following description and appended claims, or may be learned by the practice of such implementations as set forth hereinafter.

### BRIEF DESCRIPTION OF THE DRAWINGS

In order to describe the manner in which the above-recited and other features of the disclosure can be obtained, a more particular description will be rendered by reference to specific implementations thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example implementations, the implementations will be described and explained with additional specificity and detail through the use of the accompanying drawings in which:

FIG. 1 illustrates an example environment for closed loop control of flowback operations in accordance with implementations of the present disclosure.

FIG. 2 illustrates an example graphical user interface in accordance with implementations of the present disclosure.

FIG. 3 illustrates an example graphical user interface in accordance with implementations of the present disclosure.

FIG. 4 illustrates an example method for automatically sending data collected at a well during flowback operations to a reservoir modelling platform in accordance with implementations of the present disclosure.

FIG. 5 illustrates components that may be included within a computer system in accordance with implementations of the present disclosure.

### DETAILED DESCRIPTION

This disclosure generally relates to systems and methods for flowback activities at a well. Typically, during flowback at a well field operators manually record and submit a report containing all processed data for each well. The field operators periodically provide the reports over email to interested parties (e.g., a client or reservoir engineer) or provide written reports to interested parties. The reservoir engineer transfers the data from the report into the modelling platform, which in turn allows the reservoir engineer to determine parameters, such as flowback progress, reservoir performance, and bottom hole pressure (BHP). The flowback progress is used in determining a choke schedule at the well. The new schedule is compared to the last, determining whether the reservoir and the bottom hole pressure (BHP) are behaving as expected. If a change at the well is required using the new schedule, the change is communicated back to the field operators through email or a phone call.

A field operator converting the data obtained at a well manually into a spreadsheet for the report is prone to human error. In the present context, human error can have significant consequences in the flowback operations (e.g., a wrong value is used in calculating pressure resulting in contamination of natural resources or causing a safety violation). Reliably automating the data sent from the field yields an improvement in the flowback operations at the well.

The systems and methods of the present disclosure automatically collects and sends the data of flowback activities collected at the field. In some implementations, the systems and methods automatically send an email with the data automatically collected to interested parties during flowback operations at a well. In some implementations, the systems and methods automatically send the data collected directly to a reservoir modelling platform during flowback operations at a well. One example of a user is a reservoir engineer. Another example of a user is a client who owns the well. The systems and methods automatically send the data during flowback operations at a well. The systems and methods remove the manual transcription of the data collected into a report and sending the email with the report to the user. As will be discussed in further detail below, the present disclosure includes a number of practical applications having features described herein that provide benefits and/or solve problems associated with flowback activities at a well.

Some example benefits are discussed herein in connection with various features and functionalities provided on one or more computing devices. It will be appreciated that benefits explicitly discussed in connection with one or more implementations described herein are provided by way of example and are not intended to be an exhaustive list of all possible benefits of the well flowback tool. For example, one benefit includes automatic sending of field data to a reservoir modelling platform. Another example benefit includes accurate reporting of data more frequently improving data richness during operations leading to increasing overall flowback efficiency by minimizing variation between desired (model) and actual (process). Another example benefit includes running an offline model locally in areas with limited internet connectivity.

The systems and methods securely transmit the data collected at the edge (e.g., the data collected at the well) to an endpoint hosting the reservoir modelling platform or to an email distribution list. In some implementations, the endpoint hosting the reservoir modelling platform is in direct communication with the to the acquisition system collecting the data. In some implementations, there may be multiple endpoints between the acquisition system and the reservoir modelling platform. For example, the reservoir modelling platform is in communication with a flowback platform that communicates with the acquisition system collecting the data from the well. In some implementations, the reservoir modelling platform is hosted remote from the wellsite in the cloud (e.g., on a cloud server). In some implementations, the reservoir modelling platform is hosted locally at the wellsite (e.g., on an edge computing device). In some implementations, users have an on-premise instance of the reservoir modelling platform.

In some implementations, the data collected is transmitted to the reservoir modelling platform as acquired and updates the reservoir modelling platform in real-time. In some implementations, the data collected is transmitted to the reservoir modelling platform at a defined interval (e.g., every minute) and updates the reservoir modelling platform in near real time. Automatically sending the data in real-time or near real-time to the reservoir modelling platform provides accurate reporting of the well while reducing operator activities onsite.

In some implementations, the systems and methods receive an output of the reservoir modelling platform. For example, control systems at the well receive the output of the reservoir model and use the output in controlling operations at the well providing a full closed loop automation of flowback operations. The output of the reservoir modelling platform is fed back to a closed loop control system at the well, providing a full end-to-end autonomous system updating the control systems at the well.

In some implementations, the systems and methods use a locally deployed reservoir modelling platform at the field to account for any loss of communication to a remote reservoir modelling platform. For example, the local reservoir modelling platform is used in locations with low network connectivity. Another example includes the local reservoir modelling platform is used in locations where network connectivity is unavailable.

One of the technical advantages of the systems and methods of the present disclosure is improvement in data accuracy. The systems and methods automatically provide the operational data from the well in near real time removing human error imposed by manually providing the operational data from the well. Another technical advantage of the systems and methods of the present disclosure is providing a closed loop automation of flowback operations at a well. The systems and methods send data more often allowing for more timely response based on current workflows as compared to existing systems that have an operator manually send the reports hourly. The systems and methods may automatically update control parameters of equipment at the well in response to the data obtained in real time or near real time from the well.

One example use of the systems and methods of the present disclosure is for BHP. Acquisition systems at the well collect and process data related to the BHP and send the data in real-time to the reservoir modelling platform and receive an updated BHP from the reservoir modelling platform in response to the reservoir modelling platform using the data to compute the updated BHP. The updated BHP is used as a controller setpoint for the flowback system to regulate the choke. Another example use of the systems and methods of the present disclosure is automatically compensating for any erosion identified in the data of interest removing traditional workflows of choke bean size. Existing solutions schedule quoting choke bean size and if the bean erodes, maintenance is performed using the choke bean size is the reference parameter.

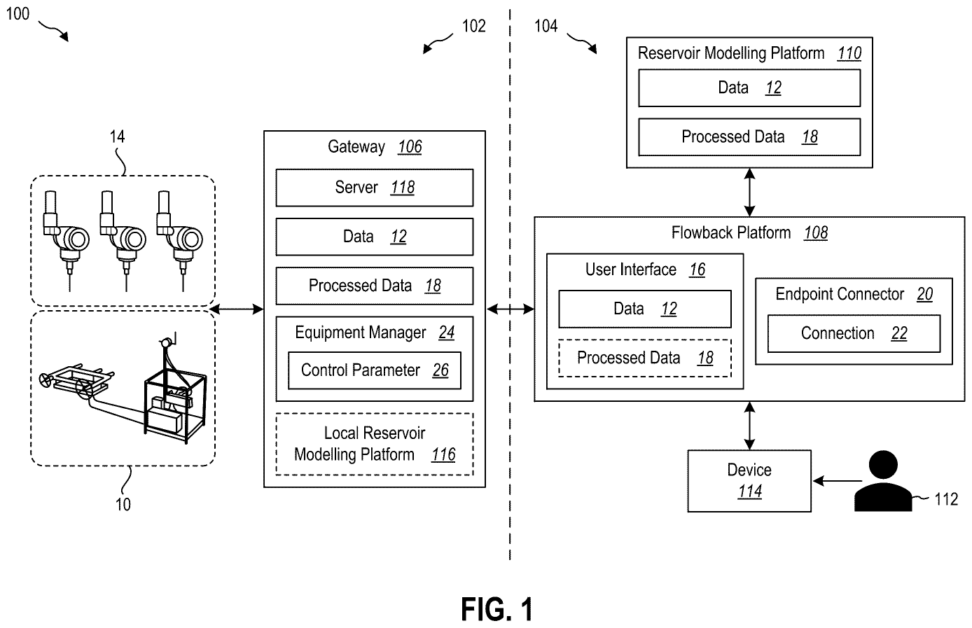

FIG. 1 illustrates an example environment 100 for closed loop control of flowback operations at a well. In some implementations, the flowback operations include well testing. Well testing occurs before long term production at the well and can take between three to eight weeks. In some implementations, the flowback operations include production. Production is when the well is producing fluids and can last between ten to twenty years. In some implementations, the well is a downhole system. In some implementations, the well is located in North America. The environment 100 includes a flowback edge system 102 located nearby the well and a flowback cloud system 104 located remote from the well.

The flowback edge system 102 provides compute capabilities nearby the well. In some implementations, the flowback edge system 102 includes a gateway 106 in communication with sensors on equipment 10 at the well. In some implementations, the sensors obtain the data 12 from the well. One example of the data 12 includes measurements (e.g., measurements of pressure, measurements of temperature). For example, sensors on the equipment 10 at the well monitor sustained annulus pressure to ensure there are no leaks. Another example includes sensors on the equipment monitoring production fluid pressure from the wellbore and temperature variations. Another example of the data 12 includes flow rates. For example, sensors on the equipment 10 at the well monitor flow rates ensuring that the flow rates remain within a safe operating envelope (SOE) with flow meters. Another example includes sensors of the equipment 10 at the well monitor PVT (pressure, volume, temperature) measurements to ensure that both the reservoir and surface equipment are operating within a safe operating envelope. Another example of the data 12 includes erosion calculations. For example, sensors on the equipment 10 at the well monitor erosion of the choke preventing damage to a formation from particles plugging the well which can cause long-term damage to the formation. Another example of the data 12 includes reservoir information. Another example of the data 12 include geological information.

In some implementations, the sensors send the data 12 to a server 118 at the gateway 106 over a network using transmitters 14. The server 118 may include one or more computing devices (e.g., including processing units, data storage, etc.) organized in an architecture with various network interfaces for connecting to and providing data management and distribution across one or more client systems.

The network may include one or multiple networks and may use one or more communication platforms and/or technologies suitable for transmitting data. The network may refer to any data link that enables transport of electronic data between devices of the environment 100. The network may refer to a hardwired network, a wireless network, or a combination of a hardwired network and a wireless network. In some implementations, the network includes a local area network (LAN). In one or more implementations, the network includes the internet. In some implementations, the network includes cellular connectivity. The network may be configured to facilitate communication between the various computing devices via well-site information transfer standard markup language (WITSML) or similar protocol, or any other protocol or form of communication.

In some implementations, the gateway 106 communicates the data 12 to a flowback platform 108 at the flowback cloud system 104 via the network. For example, the flowback platform 108 is hosted on virtual machines in the cloud. Another example includes the flowback platform 108 is hosted on a server in the cloud. In some implementations, the network includes a wide area network (WAN). In some implementations, the data 12 is transmitted to the flowback platform 108 via the network as the data 12 is acquired by the gateway 106 from the sensors. In some implementations, the data 12 is transmitted at defined intervals to the flowback platform 108. One example interval is every minute. Another example interval is every five minutes. Providing the data 12 from the gateway 106 at the edge to the flowback platform 108 in real time or near real time provides insights on the flowback activities occurring at the well.

In some implementations, the flowback platform 108 provides a user interface 16 that presents the data 12 that a user 112 accesses to view the data 12. In some implementations, the user 112 accesses the user interface 16 using a device 114. For example, a uniform resource locator (URL) configured to an end point of the flowback platform 108 is provided to the device 114 that the user 112 may access using a browser on the device 114. Another example includes an application on the device 114 of the user 112 providing access to the flowback platform 108. The device 114 may be representative of one or multiple devices and may refer to various types of computing devices. For example, the device 114 may include a mobile device such as a mobile telephone, a smartphone, a personal digital assistant (PDA), a tablet, a laptop, or any other portable device. Additionally, or alternatively, the device 114 may include one or more non-mobile devices such as a desktop computer, server device, surface or downhole processor or computer (e.g., associated with a sensor, system, or function of the downhole system), or other non-portable device. In some implementations, a user interface is displayed on a display of the device 114 providing a display of information.

In some implementations, the data 12 is updated on the user interface 16 as the data is received from the gateway 106. Updating the data 12 on the user interface 16 as the data 12 is received from the gateway 106 presents accurate real time measurements from the well. For example, real time flow rates and pressures are automatically sent to the flowback platform 108 from the well. In some implementations, the user interface 16 provides contextualization of the data 12 received from the well. One example includes the flowback platform 108 presenting the data 12 received in a table. For example, a new row is added to the table with a timestamp and the new data 12 received from the gateway 106. Another example includes a graph is presented with the data 12 and the graph is updated as new data 12 is received from the gateway 106. In some implementations, the user interface 16 provides reporting of the data 12 to a define group of users.

In some implementations, the data 12 is used by the user 112 to track the flowback operations at the well in real time or near real time. In some implementations, the data 12 is used by the user 112 to perform an action at the well. In some implementations, the data 12 is used by the user 112 to modify the equipment 10 at the well. In some implementations, the data 12 is used by the user 112 to modify drilling at the well. In some implementations, the data 12 is used by the user 112 to ensure compliance with regulatory rules governing drilling of the well. In some implementations, the data 12 is used by the user 112 to ensure compliance with safety regulations.

In some implementations, the flowback platform 108 includes an endpoint connector 20 that communicates with a reservoir modelling platform 110. The endpoint connector 20 establishes a secure connection 22 with the reservoir modelling platform 110 for transmitting the data 12. The endpoint connector 20 identifies a source of the data 12 to provide to the reservoir modelling platform 110. For example, the endpoint connector 20 receives a well identifier to supply the data 12. The well identifier associates the data to a specific well. One example of a well identifier is a well name. Another example of a well identifier is an American Petroleum Institute (API) number for the well. Another example includes the endpoint connector 20 receives a plurality of well identifiers to supply the data 12. The endpoint connector 20 identifies a start of a job (e.g., the flowback operations are occurring at the well) and sends the data 12 to the reservoir modelling platform 110 in response to the job starting.

In some implementations, the endpoint connector 20 identifies the data 12 to send to the reservoir modelling platform 110. For example, the endpoint connector 20 identifies a subset of the data 12 received from the well to send to the reservoir modelling platform 110. One example includes identifying a subset of data from pressure sensors at the well to send to the reservoir modelling platform 110. For example, the endpoint connector 20 identify fields in the data 12 relating to pressure and obtains the data 12 tagged as relating to pressure and sends the data 12 relating to pressure to the reservoir modelling platform 110. In some implementations, the endpoint connector 20 performs a mapping between the identified data (e.g., the subset of data to send) and the reservoir modelling platform 110. In some implementations, the endpoint connector 20 continues to send the data 12 to the reservoir modelling platform 110 until the job moves to a complete status (e.g., flowback is complete).

The endpoint connector 20 pushes the data 12 to the reservoir modelling platform 110 as the data 12 is received by the flowback platform 108 using the connection 22. In some implementations, the reservoir modelling platform 110 is owned by a third party and the endpoint connector 20 receives security credentials to use in accessing the reservoir modelling platform 110. For example, the endpoint connector 20 receives a server address for accessing for the reservoir modelling platform 110 and a password to use in accessing the reservoir modelling platform 110. The endpoint connector 20 establishes a secure connection 22 for communicating with the reservoir modelling platform 110 using the security credentials.

In some implementations, the endpoint connector 20 receives processed data 18 from the reservoir modelling platform 110. The processed data 18 takes raw data from field devices (actuator position, pressure, mass flow rates) and processes the raw data into datasets, such as choke bean size, blockage coefficient, volumetric flow and standard conditions. One example of the processed data 18 is BHP or choke bean size. The reservoir modelling platform 110 receives the data 12 from the flowback platform 108 and generates the processed data 18 in response to computations performed by the reservoir modelling platform 110. The flowback platform provides the processed data 18 to the gateway 106 via the network. The reservoir modelling platform 110 is updated in real time with the data 12 obtained from the well and provides processed data 18 based on the activities occurring at the well.

In some implementations, the gateway 106 includes an equipment manager 24 that receives the processed data 18 from the flowback platform 108. The equipment manager 24 uses the processed data 18 in determining a control parameter 26 for the equipment 10 at the well. In some implementations, the control parameter 26 modifies a performance of the equipment 10 at the well. In some implementations, the control parameter 26 maintains an action of the equipment 10 at the well. One example of a control parameter 26 includes a choke control and the equipment manager 24 modifies the choke control using the processed data 18 to maintain steady flow rates eliminating loss in production of the well. For example, the equipment manager 24 receives the BHP (the processed data 18) calculated by the reservoir modelling platform 110 and uses the BHP as a control parameter 26 to the choke (the equipment 10) for BHP regulation. The gateway 106 provides a closed loop automation of flowback operations at a well by automatically providing the data 12 to the flowback platform 108, receiving the processed data 18 from the flowback platform 108, and using the processed data 18 in determining a control parameter 26 for the equipment 10.

In some implementations, the control parameter 26 directly controls the equipment 10 at the well. An example of a control parameter 26 is a choke size. For example, the equipment manager 24 provides a recommended choke size in the control parameter 26 to protect the formation and fracture quality and the choke size is updated to the recommended choke size.

In some implementations, the gateway 106 includes a local reservoir modelling platform 116. In some implementations, the local reservoir modelling platform 116 receives the data 12 directly from the equipment 10 and provides the processed data 18 to the gateway 106 to use in determining the control parameter 26 for the equipment 10. In some implementations, the local reservoir modelling platform 116 provides the processed data 18 locally at the flowback edge system 102 nearby the well without connecting to the flowback cloud system 104. In some implementations, the local reservoir modelling platform 116 provides an offline solution without a requirement for a cloud option. In some implementations, the local reservoir modelling platform 116 provides an offline solution when internet connectivity is low or unavailable. For example, the local reservoir modelling platform 116 is used in locations with low network connectivity. Another example includes the local reservoir modelling platform 116 is used in locations with no network connectivity.

The environment 100 provides a full end-to-end autonomous system updating the control systems at the well in response to the data 12 obtained at the well.

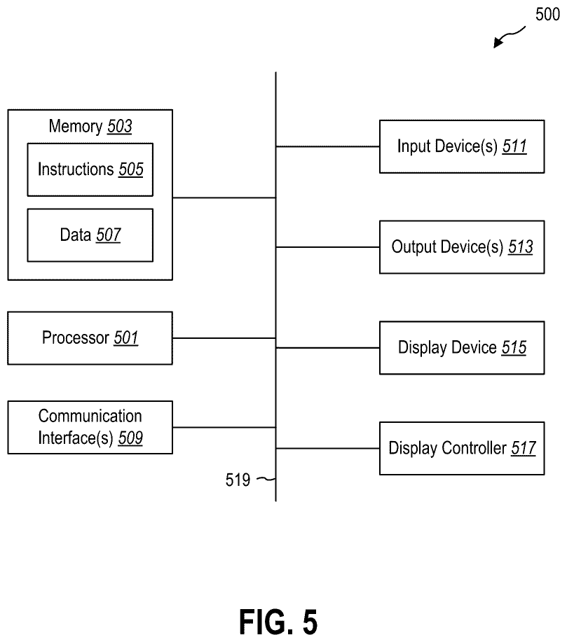

In some implementations, one or more computing devices (e.g., servers and/or devices) are used to perform the processing of the environment 100. The one or more computing devices may include, but are not limited to, server devices, cloud virtual machines, personal computers, a mobile device, such as, a mobile telephone, a smartphone, a PDA, a tablet, or a laptop, and/or a non-mobile device. The features and functionalities discussed herein in connection with the various systems may be implemented on one computing device or across multiple computing devices. Moreover, in some implementations, one or more subcomponents of the feature and functionalities discussed herein may be implemented and processed on different server devices of the same or different cloud computing networks. In this way, the environment 100 may be a cloud computing environment implemented across one or more devices of the cloud computing environment in order to leverage the processing capabilities, memory capabilities, connectivity, speed, etc., that such cloud computing environments offer in order to facilitate the features and functionalities described herein. Each of the devices of the environment 100 may include features and/or functionalities described below in connection with FIG. 5.

In some implementations, each of the components of the environment 100 is in communication with each other using any suitable communication technologies. In addition, while the components of the environment 100 are shown to be separate, any of the components or subcomponents may be combined into fewer components, such as into a single component, or divided into more components that may serve a particular implementation. In some implementations, the components of the environment 100 include hardware, software, or both. For example, the components of the environment 100 may include one or more instructions stored on a computer-readable storage medium and executable by processors of one or more computing devices. When executed by the one or more processors, the computer-executable instructions of one or more computing devices can perform one or more methods described herein. In some implementations, the components of the environment 100 include hardware, such as a special purpose processing device to perform a certain function or group of functions. In some implementations, the components of the environment 100 include a combination of computer-executable instructions and hardware.

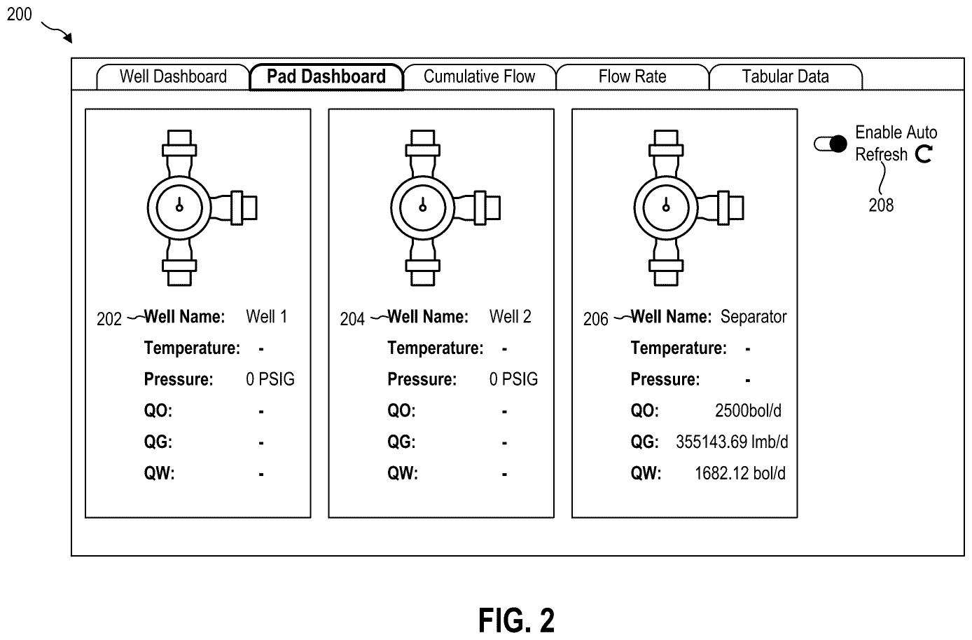

FIG. 2 illustrates an example graphical user interface (GUI) 200 presented on the user interface 16 (FIG. 1) of the flowback platform 108 (FIG. 1). The GUI 200 displays three different wells 202, 204, 206 and the data 12 (FIG. 1) received at the flowback platform 108 for each of the wells 202, 204, 206. For example, a gateway 106 (FIG. 1) located at each well 202, 204, 206 sends the data 12 to the flowback platform 108. Another example includes a single gateway 106 located near the wells 202, 204, 206 sends the data from the wells 202, 204, 206 to the flowback platform 108.

The data 12 includes a well identifier, a temperature measurement, and a pressure measurement for each well 202, 204, 206. In some implementations, the user 112 (FIG. 1) selects an icon 208 enabling automatically refreshing the data 12 and the GUI 200 updates the data 12 presented as new data 12 is received at the flowback platform 108 from the gateway 106. The GUI 200 enables automatic reporting of the data 12 obtained at each well 202, 204, 206 and allows the user 112 to track changes in the data 12 in real time or near real time.

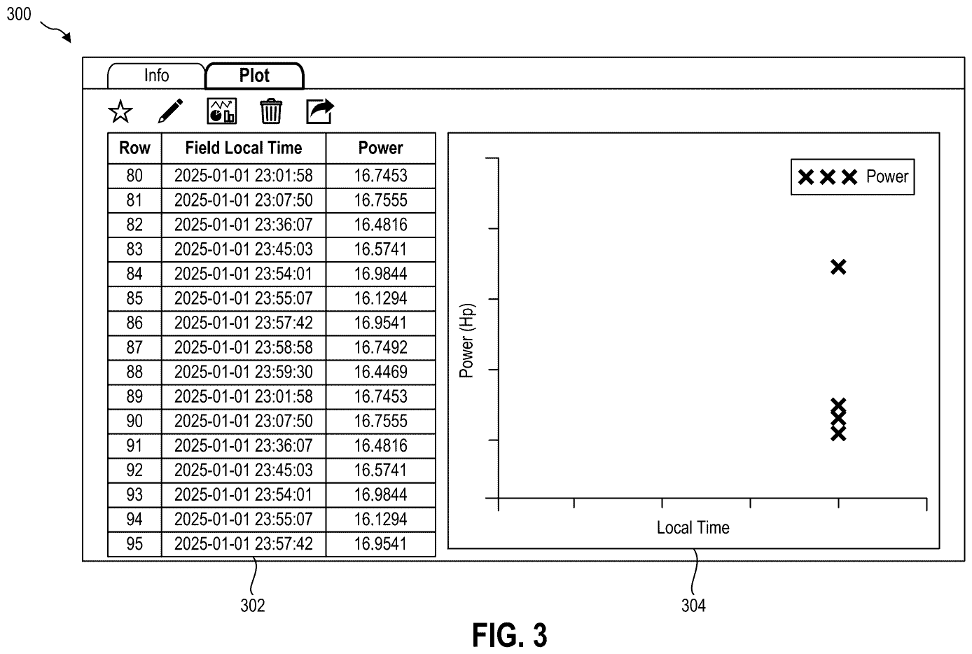

FIG. 3 illustrates an example graphical user interface (GUI) 300 presented on the user interface 16 (FIG. 1) of the flowback platform 108 (FIG. 1). The GUI 300 displays a table 302 and a graph 304 of the data 12 (FIG. 1) received at the flowback platform 108 from the gateway 106 (FIG. 1). In the illustrated example, the table 302 includes a column with a timestamp (e.g., a time when the data 12 was obtained from the well) and a column with a power measurement (e.g., the data 12) obtained from the well. For example, the data 12 is provided to the flowback platform 108 every minute. The graph 304 plots the power measurement (e.g., the data 12) over time.

In some implementations, as the data 12 is received at the flowback platform 108, the table 302 and the graph 304 are updated with the new data 12. For example, a new row is added to the table 302 with a timestamp and the new power measurement as the new data arrives at the flowback platform 108. Another example includes a new plot is added to the graph 304 with the new data 12 as the new data arrives at the flowback platform 108. The GUI 300 displays the data 12 in an easy to view manner. For example, the user 112 (FIG. 1) uses the GUI 300 to track trends in the data 12 and to ensure the well is operating as expected.

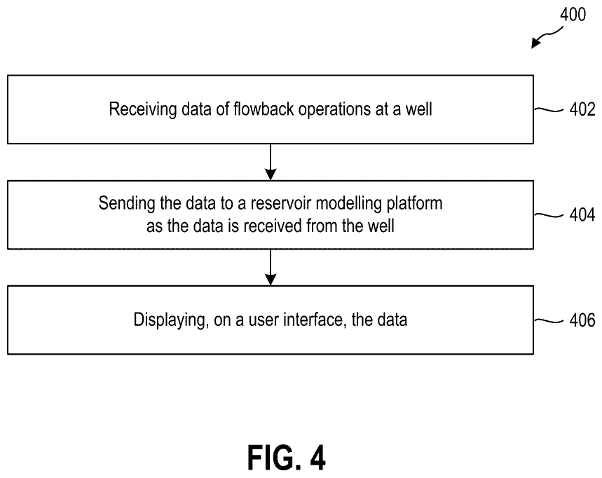

FIG. 4 illustrates an example method 400 for automatically sending data collected at a well during flowback operations to a reservoir modelling platform. The actions of the method 400 are discussed below in reference to FIGS. 1-3.

At 402, the method 400 includes receiving data of flowback operations at a well. In some implementations, a flowback platform 108 receives, via a network, the data 12 of flowback operations at a well. In some implementations, the data 12 is obtained from a sensor on equipment 10 at the well. In some implementations, the data 12 is automatically sent from a gateway 106 located at the edge (e.g., at the flowback edge system 102) nearby the well to the flowback platform 108. For example, the gateway 106 is in communication with the sensor on the equipment 10 via a local area network and the gateway 106 is in communication with the flowback platform 108 via a wide area network.

In some implementations, the data 12 is received as the data 12 is obtained by the sensor on the equipment 10 at the well. For example, the flowback platform 108 automatically receives the data 12 in real time as the data 12 is obtained by the sensor on the equipment 10 at the well. In some implementations, the data 12 is received at periodic intervals from the well. For example, the gateway 106 stores the data 12 from the sensor and transmits the data 12 to the flowback platform 108 every two minutes.

At 404, the method 400 includes sending the data to a reservoir modelling platform as the data is received from the well. In some implementations, the flowback platform 108 automatically sends the data 12 to the reservoir modelling platform 110 as the data 12 is received from the well using a secure connection established with the reservoir modelling platform 110. Automatically sending the data 12 in real-time or near real-time to the reservoir modelling platform 110 provides the reservoir modelling platform 110 accurate reporting of the flowback activities at the well.

In some implementations, the reservoir modelling platform 110 is located remote from the well at the flowback cloud system 104. In some implementations, the reservoir modelling platform 110 is owned by a third party and the secure connection uses security credentials supplied by the third party for accessing the reservoir modelling platform 110. In some implementations, the reservoir modelling platform (e.g., the local reservoir modelling platform 116) is located at the edge (e.g., at the flowback edge system 102) nearby the well. In some implementations, the user 112 has an on-premise instance of the reservoir modelling platform 110. In some implementations, the reservoir modelling platform receives the data 12 directly from the sensor on the equipment 10.

In some implementations, the method 400 optionally includes receiving from the reservoir modelling platform 110, processed data 18 in response to the reservoir modelling platform 110 processing the data 12. For example, the gateway 106 receives the processed data 18 from the reservoir modelling platform 110 in response to the reservoir modelling platform 110 processing the data 12.

In some implementations, the processed data 18 is sent to the gateway 106 located nearby the well and the processed data 18 is used in adjusting a control parameter 26 of equipment 10 at the well based on the data 12 obtained in real time from the well. In some implementations, the control parameter 26 is used to directly control the equipment 10 at the well.

At 406, the method 400 includes displaying, on a user interface, the data. In some implementations, the flowback platform 108 displays on a user interface 16 the data 12. In some implementations, the flowback platform 108 updates on the user interface 16 the data 12 as the data 12 is received from the well. In some implementations, the user 112 uses the user interface 16 to track the flowback operations at the well in real time or near real time.

The method 400 is used for automatically sending the data 12 collected at a well during flowback operations to a reservoir modelling platform 110. The method 400 is also used for automatic reporting of the data 12 obtained at the well during flowback operations.

Turning now to FIG. 5, this figure illustrates certain components that may be included within a computer system 500. One or more computer systems 500 may be used to implement the various devices, components, and systems described herein.

The computer system 500 includes a processor 501. The processor 501 may be a general-purpose single-or multi-chip microprocessor (e.g., an Advanced RISC (Reduced Instruction Set Computer) Machine (ARM)), a special purpose microprocessor (e.g., a digital signal processor (DSP)), a microcontroller, a programmable gate array, etc. The processor 501 may be referred to as a central processing unit (CPU). Although just a single processor 501 is shown in the computer system 500 of FIG. 5, in an alternative configuration, a combination of processors (e.g., an ARM and DSP) could be used.

The computer system 500 also includes memory 503 in electronic communication with the processor 501. The memory 503 may include computer-readable storage media and can be any available media that can be accessed by a general purpose or special purpose computer system. Computer-readable media that store computer-executable instructions are non-transitory computer-readable media (device). Computer-readable media that carry computer-executable instructions are transmission media. Thus, by way of example and not limitations, implementation of the present disclosure can comprise at least two distinctly different kinds of computer-readable media: non-transitory computer-readable media (devices) and transmission media.

Both non-transitory computer-readable media (devices) and transmission media may be used temporarily to store or carry software instructions in the form of computer readable program code that allows performance of implementations of the present disclosure. Non-transitory computer-readable media may further be used to persistently or permanently store such software instructions. Examples of non-transitory computer-readable storage media include physical memory (e.g., RAM, ROM, EPROM, EEPROM, etc.), optical disk storage (e.g., CD, DVD, HDDVD, Blu-ray, etc.), storage devices (e.g., magnetic disk storage, tape storage, diskette, etc.), flash or other solid-state storage or memory, or any other non-transmission medium which can be used to store program code in the form of computer-executable instructions or data structures and which can be accessed by a general purpose or special purpose computer, whether such program code is stored or in software, hardware, firmware, or combinations thereof.

Instructions 505 and data 507 may be stored in the memory 503. The instructions 505 may be executable by the processor 501 to implement some or all of the functionality disclosed herein. Executing the instructions 505 may involve the use of the data 507 that is stored in the memory 503. Any of the various examples of modules and components described herein may be implemented, partially or wholly, as instructions 505 stored in memory 503 and executed by the processor 501. Any of the various examples of data described herein may be among the data 507 that is stored in memory 503 and used during execution of the instructions 505 by the processor 501.

A computer system 500 may also include one or more communication interfaces 509 for communicating with other electronic devices. The communication interface(s) 509 may be based on wired communication technology, wireless communication technology, or both. Some examples of communication interfaces 509 include a Universal Serial Bus (USB), an Ethernet adapter, a wireless adapter that operates in accordance with an Institute of Electrical and Electronics Engineers (IEEE) 802.11 wireless communication protocol, a Bluetooth® wireless communication adapter, and an infrared (IR) communication port.

The communication interfaces 509 may connect the computer system 500 to a network. A “network” or “communications network” may generally be defined as one or more data links that enable the transport of electronic data between computer systems and/or modules, engines, or other electronic devices, or combinations thereof. When information is transferred or provided over a communication network or another communications connection (either hardwired, wireless, or a combination of hardwired or wireless) to a computing device, the computing device properly views the connection as a transmission medium. Transmission media can include a communication network and/or data links, carrier waves, wireless signals, and the like, which can be used to carry desired program or template code means or instructions in the form of computer-executable instruction or data structures and which can be accessed by a general purpose or special purpose computer.

A computer system 500 may also include one or more input devices 511 and one or more output devices 513. Some examples of input devices 511 include a keyboard, mouse, microphone, remote control device, button, joystick, trackball, touchpad, and lightpen. Some examples of output devices 513 include a speaker and a printer. One specific type of output device that is typically included in a computer system 500 is a display device 515. Display devices 515 used with implementations disclosed herein may utilize any suitable image projection technology, such as liquid crystal display (LCD), light-emitting diode (LED), gas plasma, electroluminescence, or the like. A display controller 517 may also be provided, for converting data 507 stored in the memory 503 into one or more of text, graphics, or moving images (as appropriate) shown on the display device 515.

The various components of the computer system 500 may be coupled together by one or more buses, which may include one or more of a power bus, a control signal bus, a status signal bus, a data bus, other similar components, or combinations thereof. For the sake of clarity, the various buses are illustrated in FIG. 5 as a bus system 519.

The techniques described herein may be implemented in hardware, software, firmware, or any combination thereof, unless specifically described as being implemented in a specific manner. Any features described as modules, components, or the like may also be implemented together in an integrated logic device or separately as discrete but interoperable logic devices. If implemented in software, the techniques may be realized at least in part by a non-transitory processor-readable storage medium comprising instructions that, when executed by at least one processor, perform one or more of the methods described herein. The instructions may be organized into routines, programs, objects, components, data structures, etc., which may perform particular tasks and/or implement particular data types, and which may be combined or distributed as desired in various implementations.

Further, upon reaching various computer system components, program code in the form of computer-executable instructions or data structures can be transferred automatically or manually from transmission media to non-transitory computer-readable storage media (or vice versa). For example, computer executable instructions or data structures received over a network or data link can be buffered in memory (e.g., RAM) within a network interface module (NIC), and then eventually transferred to computer system RAM and/or to less volatile non-transitory computer-readable storage media at a computer system. Thus, it should be understood that non-transitory computer-readable storage media can be included in computer system components that also (or even primarily) utilize transmission media.

### INDUSTRIAL APPLICABILITY

The following description from ¶¶ [0013]-[0065] includes various implementations that, where feasible, may be combined in any permutation. For example, the implementation of ¶¶ [0013]-[0065] may be combined with any or all implementations of the following paragraphs. Implementations that describe acts of a method may be combined with implementations that describe, for example, systems and/or devices. Any permutation of the following paragraphs is considered to be hereby disclosed for the purposes of providing “unambiguously derivable support” for any claim amendment based on the following paragraphs. Furthermore, the following paragraphs provide support such that any combination of the following paragraphs would not create an “intermediate generalization.”

In some implementations, a method includes receiving, via a network, data of flowback operations at a well, wherein the data is obtained from a sensor on equipment at the well. The method includes sending the data to a reservoir modelling platform as the data is received from the well using a secure connection established with the reservoir modelling platform. The method includes displaying, on a user interface, the data.

In some implementations, the method includes the data is received as the data is obtained from the sensor on equipment at the well.

In some implementations, the method includes the data is received at periodic intervals from the well.

In some implementations, the method includes automatically distributing the data obtained from the sensor to a plurality of users.

In some implementations, the method includes the reservoir modelling platform is located remote from the well at a cloud service provider.

In some implementations, the method includes the reservoir modelling platform is owned by a third party and the secure connection uses security credentials supplied by the third party for accessing the reservoir modelling platform.

In some implementations, the method includes the reservoir modelling platform is located at the edge nearby the well and the reservoir modelling platform receives the data directly from the sensor on the equipment.

In some implementations, the method includes the reservoir modelling platform is located at the edge nearby the well.

In some implementations, the method includes receiving, from the reservoir modelling platform, processed data in response to the reservoir modelling platform processing the data.

In some implementations, the method includes sending, to a gateway located nearby the well, the updated data, wherein the processed data is used in adjusting a control parameter of equipment at the well based on the data obtained in real time from the well.

In some implementations, the method includes using the control parameter to directly control the equipment at the well.

In some implementations, the method includes updating, on the user interface, the data as the data is received from the well.

In some implementations, the method includes data related to bottom hole pressure.

In some implementations, the method includes sending the data in real-time to the reservoir modelling platform; receiving, from the reservoir modelling platform, an updated bottom hole pressure in response to the reservoir modelling processing the data; and using the updated bottom hole pressure in regulating a choke schedule at the well.

In some implementations, the method include data with measurements of pressure, measurements of volume, and measurements of temperature.

In some implementations, the method includes sending the data as the data is obtained to the reservoir modelling platform; receiving, from the reservoir modelling platform, processed data in response to the reservoir modelling platform processing the data; and using the processed data in ensuring reservoir equipment and surface equipment are operating within a safe operating envelope.

In some implementations, the method includes data related to erosion calculations.

In some implementations, the method includes sending the data as the data is obtained to the reservoir modelling platform; receiving, from the reservoir modelling platform, a choke bean size in response to the reservoir modelling platform processing the data; and using the choke bean size in monitoring erosion of the choke.

In some implementations, the system includes a memory to store data and instructions; and a processor operable to communicate with the memory, wherein the processor is operable to: receive, via a network, data of flowback operations at a well, wherein the data is obtained from a sensor on equipment at the well; sending the data to a reservoir modelling platform as the data is received from the well using a secure connection established with the reservoir modelling platform; and display, on a user interface, the data.

In some implementations, a computer-readable storage medium including instructions that, when executed by a processor, cause the processor to: receive, via a network, data of flowback operations at a well, wherein the data is obtained from a sensor on equipment at the well; sending the data to a reservoir modelling platform as the data is received from the well using a secure connection established with the reservoir modelling platform; and display, on a user interface, the data.

One or more specific implementations of the present disclosure are described herein. These described implementations are examples of the presently disclosed techniques. Additionally, in an effort to provide a concise description of these implementations, not all features of an actual implementation may be described in the specification. It should be appreciated that in the development of any such actual implementation, as in any engineering or design project, numerous implementation-specific decisions will be made to achieve the developers'specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

Additionally, it should be understood that references to “one implementation” or “an implementation” of the present disclosure are not intended to be interpreted as excluding the existence of additional implementations that also incorporate the recited features. For example, any element described in relation to an implementation herein may be combinable with any element of any other implementation described herein. Numbers, percentages, ratios, or other values stated herein are intended to include that value, and also other values that are “about” or “approximately” the stated value, as would be appreciated by one of ordinary skill in the art encompassed by implementations of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to implementations disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. There is no intention to invoke means-plus-function or other functional claiming for any claim except for those in which the words ‘means for’ appear together with an associated function. Each addition, deletion, and modification to the implementations that falls within the meaning and scope of the claims is to be embraced by the claims.

The terms “approximately,” “about,” and “substantially” as used herein represent an amount close to the stated amount that is within standard manufacturing or process tolerances, or which still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements. Additionally, as used herein, the term “and/or” includes any and all combinations of one or more of the associated listed items.

The present disclosure may be embodied in other specific forms without departing from its spirit or characteristics. The described implementations are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A method, comprising:
receiving, via a network, data of flowback operations at a well, wherein the data is obtained from a sensor on equipment at the well;
sending the data to a reservoir modelling platform as the data is received from the well using a secure connection established with the reservoir modelling platform; and
displaying, on a user interface, the data.

2. The method of claim 1, wherein the data is received as the data is obtained from the sensor on equipment at the well.

3. The method of claim 1, wherein the data is received at periodic intervals from the well.

4. The method of claim 1, further comprising:
automatically distributing the data obtained from the sensor to a plurality of users.

5. The method of claim 1, wherein the reservoir modelling platform is located remote from the well at a cloud service provider.

6. The method of claim 1, wherein the reservoir modelling platform is owned by a third party and the secure connection uses security credentials supplied by the third party for accessing the reservoir modelling platform.

7. The method of claim 1, wherein the reservoir modelling platform is located nearby the well and the reservoir modelling platform receives the data directly from the sensor on the equipment.

8. The method of claim 1, further comprising:
receiving, from the reservoir modelling platform, processed data in response to the reservoir modelling platform processing the data.

9. The method of claim 8, further comprising:
sending, to a gateway located nearby the well, the processed data, wherein the processed data is used in adjusting a control parameter of equipment at the well based on the data obtained in real time from the well.

10. The method of claim 9, further comprising:
using the control parameter to directly control the equipment at the well.

11. The method of claim 1, further comprising:
updating, on the user interface, the data as the data is received from the well.

12. A system, comprising:
a memory to store data and instructions; and
a processor operable to communicate with the memory, wherein the processor is operable to:
receive, via a network, data of flowback operations at a well, wherein the data is obtained from a sensor on equipment at the well;
sending the data to a reservoir modelling platform as the data is received from the well using a secure connection established with the reservoir modelling platform; and
display, on a user interface, the data.

13. The system of claim 12, wherein the processor is further operable to receive the data as the data is obtained from the sensor on equipment at the well.

14. The system of claim 12, wherein the processor is further operable to receive the data at periodic intervals from the well.

15. The system of claim 12, wherein the reservoir modelling platform is located remote from the well at a cloud service provider.

16. The system of claim 12, wherein the reservoir modelling platform is located nearby the well.

17. The system of claim 12, wherein the data is related to bottom hole pressure and the processor is further operable to:
send the data in real-time to the reservoir modelling platform;
receive, from the reservoir modelling platform, an updated bottom hole pressure in response to the reservoir modelling processing the data; and
use the updated bottom hole pressure in regulating a choke schedule at the well.

18. The system of claim 12, wherein the data includes measurements of pressure, measurements of volume, and measurements of temperature and the processor is further operable to:
send the data as the data is obtained to the reservoir modelling platform;
receive, from the reservoir modelling platform, processed data in response to the reservoir modelling platform processing the data; and
use the processed data in ensuring reservoir equipment and surface equipment are operating within a safe operating envelope.

19. The system of claim 12, wherein the data includes erosion calculations and the processor is further operable to:
send the data as the data is obtained to the reservoir modelling platform;
receive, from the reservoir modelling platform, a choke bean size in response to the reservoir modelling platform processing the data; and
use the choke bean size in monitoring erosion of the choke.

20. The system of claim 18, wherein the processor is further operable to:
send, to a gateway located nearby the well, the processed data, wherein the processed data is used in adjusting a control parameter of equipment at the well based on the data obtained in real time from the well;
use the control parameter to directly control the equipment at the well; and
update, on the user interface, the data as the data is received from the well.
